(19) United States
(12) Patent Application Publication
(10) Pub. No.: US 2026/0367172 A1
(43) Pub. Date: Nov. 19, 2026

(54) APPARATUS AND METHOD FOR MANAGING A BATTERY IN AN ELECTRIFIED VEHICLE

(71) Applicants: HYUNDAI MOTOR COMPANY, Seoul (KR); KIA CORPORATION, Seoul (KR)

(72) Inventors: Jung Heon Lee, Hwaseong-si (KR); Tae Kyu Kang, Hwaseong-si (KR); Min Jun Park, Hwaseong-si (KR)

(73) Assignees: HYUNDAI MOTOR COMPANY, Seoul (KR); KIA CORPORATION, Seoul (KR)

(21) Appl. No.: 19/353,195

(22) Filed: Oct. 8, 2025

(30) Foreign Application Priority Data
May 19, 2025 (KR) 10-2025-0064791

(51) Int. Cl. G01R 31/392; B60L 58/12; B60L 58/16; G01R 31/367; G01R 31/371; G01R 31/374; G01R 31/3842; H01M 10/42; H01M 10/48

(52) U.S. Cl. CPC G01R 31/392; B60L 58/12; B60L 58/16; G01R 31/367; G01R 31/371; G01R 31/374; G01R 31/3842; H01M 10/425; H01M 10/48; B60L 2240/545; H01M 2010/4271; H01M 2010/4278; H01M 2220/20

(57) ABSTRACT

An apparatus for managing a battery in an electrified vehicle includes a memory configured to store battery state information including State Of Charge (SOC) and integrated current values for a plurality of battery usage intervals. The apparatus also includes a processor configured to determine a battery capacity degradation value based on a relationship between the integrated current values and the SOC derived from a plurality of pieces of battery state information collected in a plurality of ignition-on intervals of the electrified vehicle. The apparatus additionally includes a communication device configured to transmit the battery capacity degradation value to one or more external devices.

### CROSS REFERENCE TO RELATED APPLICATION

The present application claims the benefit of and priority to Korean Patent Applications No. 10-2025-0064791, filed on May 19, 2025, the entire contents of which are hereby incorporated herein by reference.

### TECHNICAL FIELD

The present disclosure relates to an apparatus and method for managing a battery in an electrified vehicle.

### BACKGROUND

With a growing interest in the environment, the use of eco-friendly vehicles equipped with an electric motor as a power source is on the rise. An eco-friendly vehicle is also referred to as an electrified vehicle. Representative examples of eco-friendly vehicles include a Hybrid Electric Vehicle (HEV) an Electric Vehicle (EV).

A battery used in an electrified vehicle may be a secondary battery capable of repeated charging and discharging. Such secondary batteries may undergo degradation due to various causes such as the number of repeated charge and discharge cycles, temperature changes, and physical shocks.

Such degradation may appear in the form of a decrease in State Of Charge (SOC), which is the available capacity of a battery, and a decrease in output due to an increase in internal resistance. State Of Health (SOH) of a battery, which is an index indicating the degree of degradation of the battery, may be estimated by various methods.

The methods of estimating the SOH of a battery may be classified into capacity degradation (SOHc) directly related to driving distance and a resistance degradation (SOHr) directly related to output characteristics. In hybrid vehicles, since the battery's SOC is managed within a target operating soc range and an electric motor is used as an auxiliary power source, research on resistance degradation related to output characteristics has been continuously conducted.

The matters described in this Background section are provided merely to enhance understanding of the background of the present disclosure and should not be construed as being included in the related art known to those having ordinary skill in the art.

### SUMMARY

Embodiments of the present disclosure provide an apparatus and method for managing battery in an electrified vehicle, that may provide a reliable capacity degradation value for the battery in the electrified vehicle.

The objectives of the present disclosure are not limited to the objectives described above. Other objectives that are not described herein should be more clearly understood by those having ordinary skill in the art from the following description.

According to an embodiment, an apparatus for managing a battery in an electrified vehicle is provided. The apparatus includes a memory configured to store battery state information including State Of Charge (SOC) and integrated current values for a plurality of battery usage intervals. The apparatus also includes a processor configured to determine a battery capacity degradation value based on a relationship between the integrated current values and the SOC derived from a plurality of pieces of battery state information collected in a plurality of different ignition-on intervals of the electrified vehicle. The apparatus additionally includes a communication device configured to transmit the battery capacity degradation value to one or more external devices.

In an embodiment, the plurality of battery usage intervals may include a plurality of ignition-on intervals between ignition on (IG on) and ignition off (IG off) of the electrified vehicle.

In an embodiment, the processor may be configured to determine the battery capacity degradation value based on battery state information, among the battery state information obtained from the memory, corresponding to a predetermined SOC range.

In an embodiment, the predetermined SOC range may correspond to a target operating SOC of the electrified vehicle

In an embodiment, the processor may be configured to determine the SOC for an IG on interval, among the plurality of ignition-on intervals, based on an open circuit voltage of the battery obtained at a beginning of the ignition-on interval.

In an embodiment, the processor may be further configured to determine an integrated current value for an IG on interval, among the plurality of ignition-on intervals, based on current supplied to loads of the electrified vehicle during the ignition-on interval.

In an embodiment, the processor may be configured to determine the integrated current value further based on current supplied to the apparatus for managing the battery during the ignition-on interval.

In an embodiment, the processor may be configured to determine the battery capacity degradation value based on a set of state information including a predetermined number of pieces of battery state information obtained from the memory. The processor may be configured to exclude, from the set of state information, battery state information not corresponding to the predetermined SOC.

In an embodiment, the processor may be further configured to exclude, from the set of state information, battery state information including SOC determined at a battery temperature lower than a reference temperature.

In an embodiment, the processor may be configured to determine a capacity of the battery based on a relationship between the integrated current values included in and the Soc included in the set of state information, and determine the battery capacity degradation value based on the capacity of the battery.

In an embodiment, the processor may be configured to determine the capacity of the battery by performing regression analysis on the relationship between the integrated current values and the SOC included in the set of state information.

In an embodiment, the processor may be configured to determine a linear model representing a correlation between the integrated current values and the Soc included in the set of state information, and determine the capacity of the battery based on a slope of the linear model.

In an embodiment, the processor may be configured to newly determine capacity of the battery each time the memory stores new battery state information, and update the capacity of the battery based on a weighted combination of a previously determined capacity and a newly determined capacity.

In an embodiment, the processor may be configured to determine a larger weight for the previously determined capacity as a number of excluded pieces of state information among the state information included in the set of state information increases.

In an embodiment, the processor may be configured to determine a weight for the previously determined capacity based on consecutiveness of excluded pieces of state information among the state information included in the set of state information.

According to another embodiment, a method of managing a battery in an electrified vehicle is provided. The method includes storing battery state information including State Of Charge (SOC) and integrated current values for a plurality of ignition-on intervals of the electrified vehicle. The method also includes determining a set of state information based on a plurality of pieces of the battery state information collected in the plurality of ignition-on intervals of the electrified vehicle. The method additionally includes determining a battery capacity degradation value based on a relationship between the integrated current values and the SOC included in the set of state information. The method further includes transmitting the battery capacity degradation value to one or more controller for managing the battery.

In an embodiment, determining the set of state information may include excluding, from the set of state information, battery state information not corresponding to a target operating SOC of the electrified vehicle.

In an embodiment, determining the set of state information may further include excluding, from the set of state information, battery state information including SOC determined at a battery temperature lower than a reference temperature.

In an embodiment, the method may further include determining the SOC for an ignition-on interval, among the plurality of ignition-on intervals, based on an open circuit voltage of the battery at a beginning of the ignition-on interval. The method may also include determining an integrated current value for the ignition-on interval based on a current supplied by the battery during the ignition-on interval.

In an embodiment, determining the battery capacity degradation value may include determining a capacity of the battery based on a slope of a linear model obtained by performing linear regression analysis on a relationship between the integrated current values and the Soc included in the set of state information. The method may include determining the battery capacity degradation value based on the capacity of the battery.

According to embodiments of the present disclosure, it is possible to provide a reliable capacity degradation value for a battery of an electrified vehicle that is operated within a target operating SOC range.

The effects of the present disclosure are not limited to the effects described above. Other effects not described herein should be more clearly understood by those having ordinary skill in the art from the following description.

### BRIEF DESCRIPTION OF THE DRAWINGS

FIG. 1 is a block diagram illustrating an apparatus for managing a battery in an electrified vehicle, according to an embodiment;

FIG. 2 is a graph illustrating an example of a process in which an apparatus for managing a battery determines SOC based on an open circuit voltage of the battery, according to an embodiment;

FIG. 3 is a graph illustrating an example of a process in which an apparatus for managing a battery determines an integrated current value for each interval based on a supply current of the battery, according to an embodiment;

FIG. 4 is a graph illustrating an example of a plurality of pieces of state information stored in a memory, according to an embodiment;

FIG. 5 is a graph illustrating an example of a process in which a processor excludes some of a predetermined number of pieces of state information, according to an embodiment;

FIG. 6 is a graph illustrating an example of a process in which a processor determines the capacity of a battery by excluding some of a predetermined number of pieces of state information, according to an embodiment;

FIG. 7 is a flowchart illustrating an example of a process in which an apparatus for managing a battery stores state information of the battery during an ignition-on interval, according to an embodiment; and

FIG. 8 is a flowchart illustrating an example of a process in which an apparatus for managing a battery determines capacity degradation based on battery state information, according to an embodiment.

### DETAILED DESCRIPTION

Hereafter, embodiments of the present disclosure are described in detail with reference to the accompanying drawings. In the accompanying drawings, the same or similar components are given the same or similar reference numerals even when the components are illustrated in different drawings, duplicate descriptions thereof have been omitted. Terms “module” and “unit” that are used for components in the following description are used only for the convenience of description without having discriminate meanings or functions. In the following description, where it was decided that a detailed description of known features or functions would obscure the gist of the present disclosure, the detailed description thereof has been omitted. Further, the accompanying drawings are provided merely to enhance understanding of the embodiments described in the present disclosure. It should be understood that the technical spirit of the present disclosure is not limited by the accompanying drawings, and all changes, equivalents, and replacements should be understood as being included in the spirit and scope of the present disclosure.

Terms including ordinal numbers such as “first” and “second” may be used to describe various components, but the components are not to be construed as being limited to the terms. The terms are used only to distinguish one component from another component.

It should be understood that when one element is referred to as being “connected to” or “coupled to” another element, the element may be connected directly to or coupled directly to the other element or may be connected to or coupled to the other element with the one or more further elements therebetween. On the other hand, it should be understood that when one element is referred to as being “connected directly to” or “coupled directly to” another element, the element may be connected to or coupled to another element without other elements therebetween.

Singular forms are intended to include plural forms unless the context clearly indicates otherwise.

It should be further understood that the terms “comprise” or “have” used in this specification specify the presence of stated features, steps, operations, components, parts, or a combination thereof, but do not preclude the presence or addition of one or more other features, numerals, steps, operations, components, parts, or a combination thereof.

When a component, controller, device, element, apparatus, unit or the like of the present disclosure is described as having a purpose or performing an operation, function, or the like, the component, controller, device, element, apparatus, unit or the like should be considered herein as being “configured to” meet that purpose or to perform that operation or function. Each component, controller, device, element, apparatus, unit, or the like may separately embody or be included with one or more processors and a memory, such as a non-transitory computer-readable media, as part of the apparatus. The one or more processors may be configured to implement computer-readable instructions stored in the memory to perform the described operations.

A unit or a control unit that is included in names such as a motor control unit (MCU) is only a term that is generally used to name a controller that controls specific functions of a vehicle rather than mean a generic function unit. For example, each control unit may include a communication device that communicates with another control unit or a sensor to control corresponding functions, a memory that stores an operating system or logic commands and input/output information, and one or more processors that perform determination, calculation, decision, etc. for controlling the corresponding functions.

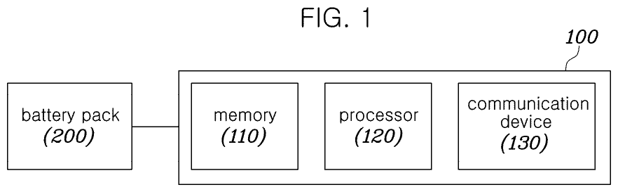

FIG. 1 is a block diagram illustrating an apparatus for managing a battery in an electrified vehicle, according to an embodiment.

Referring to FIG. 1, an apparatus 100 for managing a battery in an electrified vehicle according to an embodiment may include a memory 110, a processor 120, and a communication device 130.

The memory 110 may store various types of state information, such as voltage, current, temperature, and/or charge/discharge history of a battery 200 obtained from another controller, for each usage interval, among a plurality of usage intervals, of the battery 200. Further, the memory 110 may receive and store Soc and SOH values determined by the processor 120 based on the various types of state information.

For example, the memory 110 may store state information of the battery 200 corresponding to each interval during which the vehicle ignition remains on (from ignition-on to ignition-off). Accordingly, the memory 110 may store a plurality of pieces of battery state information corresponding to a plurality of ignition-on intervals, respectively.

The processor 120 may receive data, such as voltage, current, and/or temperature, of the battery 200 from the memory 110 and may determine the state of charge (SOC) and state of health (SOH) of the battery 200 using a predetermined calculation process. Further, the processor 120 may generate various control signals for stable operation of the battery 200.

In electrified vehicles, stable operation of the battery may be controlled by a battery controller, such as a Battery Management System (BMS). The battery management system may perform various roles such as monitoring the state of the battery's voltage, current, temperature, etc., calculating the maximum allowable power during charging or discharging, maintaining cell balancing, performing protective measures in case of risk situations such as overcurrent or short circuit, and/or recording battery charging/discharging and performance data.

The communication device 130 may perform information transmission and reception between the apparatus 100 for managing a battery and other controllers.

For example, the communication device 130 may transmit SOC and SOH information to other controllers via Controller Area Network (CAN) communication and/or receive control commands from other controllers and transmit the commands to the processor 120.

Although not illustrated, the apparatus 100 for managing a battery may further include a plurality of sensors for measuring the voltage, current, temperature, etc. of the battery 200.

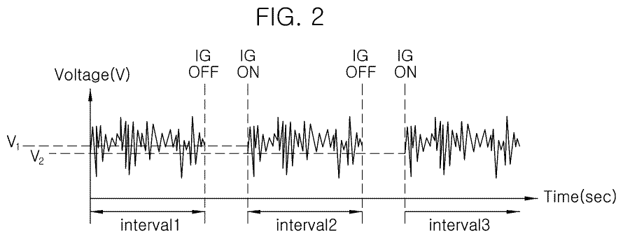

FIG. 2 is a graph illustrating an example of a process in which an apparatus (e.g., the apparatus 100 of FIG. 1) for managing a battery determines SOC based on an open circuit voltage of the battery, according to an embodiment.

Referring to FIG. 2, the voltage of the battery 200 may vary from time to time while the ignition of the vehicle remains on (IG ON). In order to obtain a consistent voltage value, the apparatus 100 for managing a battery may measure an open circuit voltage (OCV), which is the voltage immediately after the ignition of the vehicle is turned on, and may store it in the memory 110.

The processor 120 may determine the SOC of the battery 200 based on the open circuit voltage stored in the memory 110. For example, the processor 120 may determine the SOC value of the battery 200 by referring to a table or map including SOC values corresponding to the open circuit voltage of the battery 200.

In order to determine the remaining SOC, after using the battery 200 during each ignition-on interval, as the SOC value to be included in the state information for each interval, the voltage measured at the start point of the next interval, rather than the voltage measured at the start point of each interval, may be used to determine the SOC of the previous interval.

For example, the processor 120 may determine the remaining SOC (SOC₁) of interval 1 by referring to the voltage V₁ measured at the start point of interval 2, and may determine the SOC (SOC₂) of interval 2 by referring to the voltage V₂ measured at the start point of interval 3. This is merely an example, and the present disclosure is not limited thereto. For example, in another embodiment, the processor 120 may determine the remaining Soc by referring to the voltage measured at the end point of each interval.

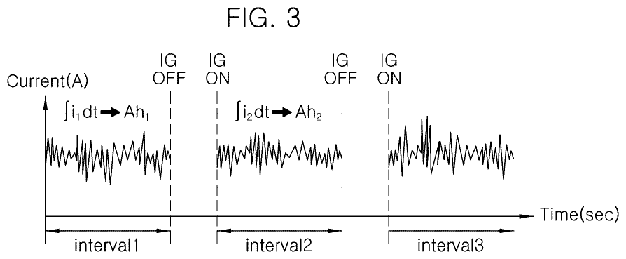

FIG. 3 is a graph illustrating an example of a process in which an apparatus e.g., the apparatus 100 of FIG. 1) for managing a battery determines an integrated current value for each interval based on a supply current of the battery, according to an embodiment.

Referring to FIG. 3, the processor 120 may determine an integrated current value to be included in the state information for each interval based on the current supplied by the battery 200 for each interval stored in the memory 110.

For example, the integrated current value Ah₁ for interval 1 may be determined based on the value obtained by integrating the current supplied by the battery 200 during interval 1 over time, and the integrated current value Ah₂ for interval 2 may be determined based on the value obtained by integrating the current supplied by the battery 200 during interval 2 over time.

In an embodiment, the apparatus 100 for managing a battery according to an embodiment may further include a Battery Monitoring Integrated Circuit (BMIC) capable of monitoring each cell state of the battery 200 and performing cell balancing. However, the current that is supplied to such a BMIC may not be included in the measurement value of the current sensor for measuring the current that is supplied to the vehicle loads. Therefore, the processor 120 may correct the integrated current value by considering the current that is supplied to the BMIC during an ignition-on interval and transmit it to the memory 110, in an embodiment.

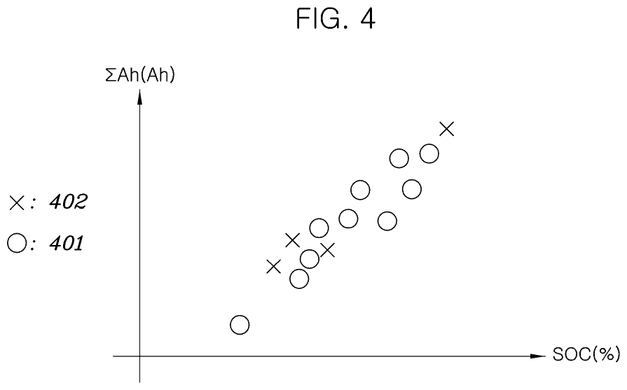

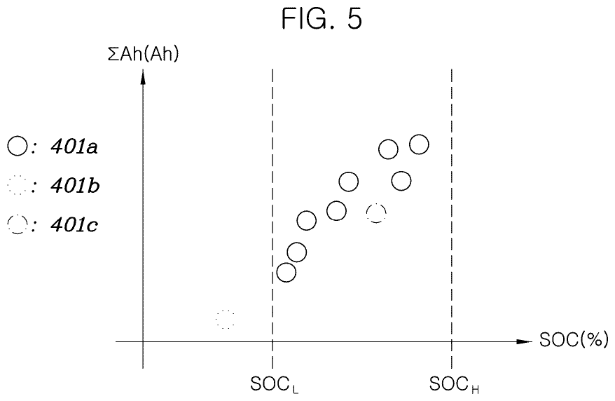

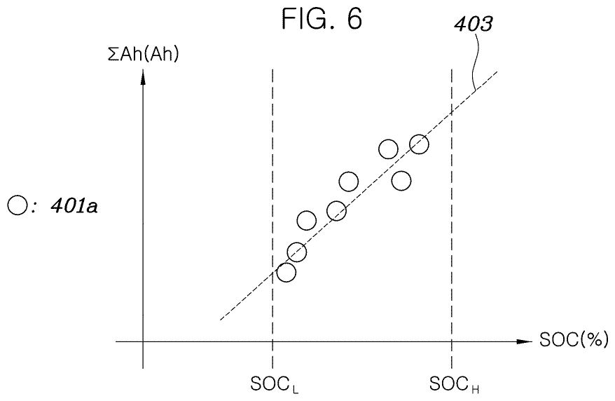

FIG. 4 is a graph illustrating an example of a plurality of pieces of state information stored in a memory (e.g., the memory 110 of FIG. 1) according to an embodiment. FIG. 5 is a graph illustrating an example of a process in which a processor (e.g., the processor 120 of FIG. 1) excludes some of a predetermined number of pieces of state information, according to an embodiment. FIG. 6 is a graph illustrating an example of a process in which a processor (e.g., the processor 120 of FIG. 1) determines the capacity of a battery by excluding some of a predetermined number of pieces of state information, according to an embodiment.

Referring to FIG. 4, among the plurality of pieces of state information stored in the memory 110, the SOC value is set as the first axis and the integrated current value Ah is set as the second axis, and a graph is shown where each coordinate on the graph represents the Soc value and integrated current value corresponding to each ignition-on interval.

The processor 120 may determine the capacity degradation (e.g., may determine a battery capacity degradation value) of the battery 200 based on a predetermined number of pieces of state information (or a set of state information) among the plurality of pieces of state information stored in the memory 110.

For example, the processor 120 may determine a set of state information including 10 pieces of state information among the plurality of pieces of state information 401 and 402 stored in the memory 110, and may determine the capacity degradation of the battery based on the set of state information. As one example of a method of determining a set of state information, the processor 120 determines the most recently stored 10 pieces of state information 401 as a set of state information and determines the capacity degradation based on the set of state information. The processor 120 may not use the remaining state information 402 to determine the capacity degradation.

Referring to FIG. 5, the processor 120 may determine capacity degradation by excluding some of a predetermined number of pieces of state information 401a, 401b, and 401c included in a set of state information to improve the accuracy of the capacity degradation.

Many electrified vehicles including hybrid vehicles may be controlled to operate the battery 200 within a predetermined range of SOC (or target operating SOC). Considering such a control method, the processor 120 may determine capacity degradation based on only state information corresponding to a specific SOC interval rather than the entire SOC range.

For example, the processor 120 may determine the capacity degradation of the battery 200 by excluding state information 401b that does not correspond to the target operating Soc (equal to or higher than SOC_{L} and equal to or lower than SOC_{H}) of a hybrid vehicle.

Further, when the apparatus 100 measures the open circuit voltage of the battery 200 in a low-temperature environment, the measurement error of the open circuit voltage may increase due to an increase in depolarization time of the battery 200 and expansion of the error ranges of sensors. In an embodiment, the processor 120 may determine capacity degradation by excluding state information 401c including SOC based on the open circuit voltage measured at a temperature of the battery 200 lower than a predetermined reference temperature among the predetermined number of pieces of state information 401a, 401b, and 401c included in the set of state information.

The processor 120 may thus determine capacity degradation based on the remaining state information 401a excluding the state information 401b that does not correspond to the target operating SOC of the electrified vehicle and the state information 401c including SOC obtained at a temperature of the battery 200 lower than the reference temperature among the predetermined number of pieces of state information 401a, 401b, and 401c included in the set of state information.

Referring to FIG. 6, the processor 120 may determine a linear model representing the correlation between an SOC value 401a included in the state information that is not excluded among predetermined state information and an accumulated current value through linear regression analysis.

As an example of a method of determining a linear model, statistical techniques such as the least squares technique or method that determines a linear model such that the square of residuals between the data included in state information and the linear model is minimized may be used.

When a linear model representing the correlation between an SOC value and an accumulated current value is determined, the capacity of the battery 200 may be determined based on relational expressions such as Equations 1 to 3 and the slope of the linear model.

$$SOC [ \% ] = \frac{Q}{C} \times 100 \qquad [ Equation 1 ]$$

$${Q}_{2} = {Q}_{1} - {\int }_{{t}_{1}}^{{t}_{2}} i ( t ) dt \qquad [ Equation 2 ]$$

$$C = \frac{{\int }_{{t}_{1}}^{{t}_{2}} i ( t ) d t}{S O C ( {t}_{1} ) - S O C ( {t}_{2} )} \qquad [ Equation 3 ]$$

In Equations 1 to 3, Q is the remaining charge of a battery, Q₁ is the remaining charge of the battery at time point t1, Q2 is the remaining charge of the battery at time point t₂, C is the capacity of the battery, and i(t) is supply current of the battery.

The process of determining capacity degradation based on the determined capacity of battery 200, according to an embodiment, is described in more detail below.

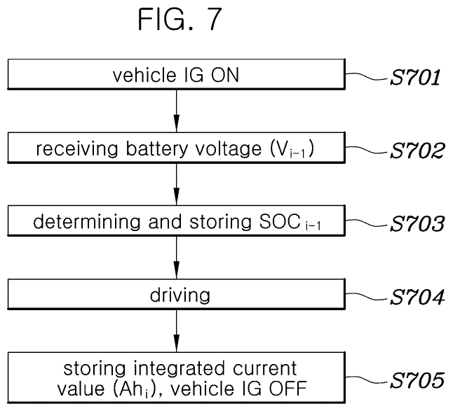

FIG. 7 is a flowchart illustrating an example of a process in which an apparatus (e.g., the apparatus 100 of FIG. 1) for managing a battery stores state information of the battery during an ignition-on interval, according to an embodiment.

Referring to FIG. 7, in a step or operation S702, the processor 120 may receive the open circuit voltage of the battery 200 measured by a voltage sensor when the ignition of the vehicle is turned on in a step or operation S701. In this case, the open circuit voltage received at the beginning of an i-th ignition-on interval may be determined as Vᵢ₋₁ corresponding to the previous interval (i−1-th interval).

In a step or operation S703, the processor 120 may determine SOCi−1 corresponding to the SOC for the previous interval based on the received open circuit voltage Vᵢ₋₁, and the memory 110 may store SOCᵢ₋₁.

In a step or operation S704, the battery 200 may supply current to various types of loads including a motor and an inverter while the vehicle is being driven. The apparatus 100 may measure the current supplied by the battery 200 through a current sensor, and the processor 120 may determine an accumulated current value Ahᵢ based on the measured current. In a step or operation S705, when the driving of the vehicle ends, the memory 110 may accumulate and store the determined accumulated current value.

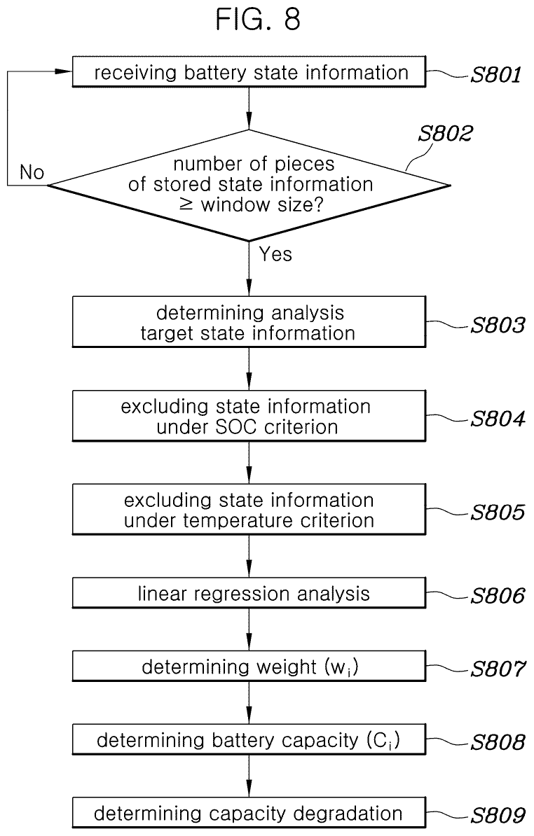

FIG. 8 is a flowchart illustrating an example of a process in which an apparatus (e.g., the apparatus 100 of FIG. 1) for managing a battery determines capacity degradation based on battery state information, according to an embodiment.

Referring to FIG. 8, in a step or operation S801, the processor 120 may receive battery state information Sᵢ for the i-th interval. The battery state information Sᵢ may include the remaining SOC (SOCᵢ) and the accumulated current value Ahᵢ during the i-th interval.

In a step or operation S802, the processor 120 may determine whether the number of pieces of state information stored in the memory 110, including the battery state information Sᵢ for the i-th interval, exceeds a predetermined window size. The predetermined window size may correspond to the number of elements to be included in a state information set.

For example, when the predetermined window size is a certain window size (e.g., 10), and the number of pieces of state information stored in the memory is smaller than that the certain window size (No in in the step or operation S802), the processor 120 may wait until new state information is received without determining the capacity degradation in the step or operation S801. On the other hand, when the number of pieces of state information stored in the memory 110 is greater than or equal to the window size (Yes in the step or operation S802), the processor 120 may determine a state information set having some of a plurality of pieces of state information as elements in a step or operation S803.

In a step or operation S804, the processor 120 may exclude, from the state information included in a state information set, state information not corresponding to the target operating SOC of the electrified vehicle. In an operation S805, the processor 120 may exclude, from the state information included in a state information set, state information including SOC obtained at a temperature of the battery 200 lower than a reference temperature amount (S804 and S805). In a step or operation 806, the processor 120 may perform linear regression analysis based on the remaining state information.

The processor 120 may determine the capacity Cᵢ of the battery 200 based on the slope of the linear model obtained through linear regression analysis. In this case, in a step or operation S807, the processor 120 may determine a weight between the existing capacity Cᵢ₋₁ obtained based on data up to the previous interval (i−1-th interval) and the capacity C_{new} obtained based on a state information set including new state information Sᵢ, and the capacity Cᵢ of the battery 200 may be newly determined by considering the determined weight in a step or operation S808.

As an example of determining the weight w for the existing capacity Cᵢ₋₁, the weight w may be determined based on the number a of pieces of state information excluded in accordance with a SOC criterion or a temperature criterion among the state information included in a state information set, the number b of consecutive excluded pieces of state information, and the window size L.

For example, in accordance with a predetermined window size (e.g., L=10), a total of 10 pieces of state information S₁ to S₁₀ may be included in a state information set, and among them, four pieces of state information S₂, S₃, S₄, and S₇ may be excluded in accordance with a SOC criterion and a temperature criterion. In this case, since four pieces of state information are excluded in accordance with the SOC criterion and the temperature criterion, the value a may be determined as 4, and since three pieces of state information S₂, S₃, and S₄ are consecutively excluded, the value b may be determined as 3.

Further, the weight w considering all of the window size L, the number a of excluded pieces of state information, and the consecutiveness b may be determined based on Equation 4, and the capacity Cᵢ of the battery 200 to which the weight wᵢ determined by considering the battery state information Sᵢ of the i-th interval is applied may be determined based on Equation 5.

w=(a+b)/2L [Equation 4]

Cᵢ=wᵢ*Cᵢ₋₁+(1−wᵢ)*C_{new} [Equation 5]

In a step or operation S809, the processor 120 may determine capacity degradation (SOHc) of the battery of the battery 200 based on the determined capacity Cᵢ of the battery as shown in the following Equation 6.

$$SOHc [ \% ] = \frac{{c}_{i}}{{c}_{B O L}} \times 100 \qquad [ Equation 6 ]$$

In Equation 6, C_{BOL} is the battery capacity measured at the Beginning Of Life.

Although the present disclosure was provided above with reference to embodiments shown in the accompanying drawings, it should be apparent to those having ordinary skill in the art that the present disclosure may be changed and modified in various ways without departing from the spirit and scope of the present disclosure defined by the appended claims.

What is claimed is:

1. An apparatus for managing a battery in an electrified vehicle, the apparatus comprising:
a memory configured to store battery state information including State Of Charge (SOC) and integrated current values for a plurality of battery usage intervals;
a processor configured to determine a battery capacity degradation value based on a relationship between the integrated current values and the SOC derived from a plurality of pieces of battery state information collected in a plurality of different ignition-on intervals of the electrified vehicle; and
a communication device configured to transmit the battery capacity degradation value to one or more external devices.

2. The apparatus of claim 1, wherein the plurality of battery usage intervals includes a plurality of ignition-on intervals between ignition on (IG on) and ignition off (IG off) of the electrified vehicle.

3. The apparatus of claim 1, wherein the processor is configured to determine the battery capacity degradation value based on battery state information, among the battery state information obtained from the memory, corresponding to a predetermined SOC range.

4. The apparatus of claim 3, wherein the predetermined soc range corresponds to a target operating SOC of the electrified vehicle.

5. The apparatus of claim 2, wherein the processor is further configured to determine the SOC for an ignition-on interval, among the plurality of ignition-on intervals, based on an open circuit voltage of the battery obtained at a beginning of the ignition-on interval.

6. The apparatus of claim 2, wherein the processor is further configured to determine an integrated current value for an ignition-on interval, among the plurality of ignition-on intervals, based on current supplied to loads of the electrified vehicle during the ignition-on interval.

7. The apparatus of claim 6, wherein the processor is configured to determine the integrated current value further based on current supplied to the apparatus for managing the battery during the ignition-on interval.

8. The apparatus of claim 3, wherein the processor is configured to determine battery capacity degradation value based on a set of state information including a predetermined number of pieces of battery state information obtained from the memory, wherein the processor is configured to exclude, from the set of state information, battery state information not corresponding to the predetermined SOC range.

9. The apparatus of claim 8, wherein the processor is further configured to exclude, from the set of state information, battery state information including SOC determined at a battery temperature lower than a reference temperature.

10. The apparatus of claim 8, wherein the processor is configured to:
determine a capacity of the battery based on a relationship between the integrated current values and the SOC included in the set of state information; and
determine the battery capacity degradation value based on the capacity of the battery.

11. The apparatus of claim 10, wherein the processor is configured to determine the capacity of the battery by performing regression analysis on the relationship between the integrated current values and the Soc included in the set of state information.

12. The apparatus of claim 11, wherein the processor is configured to:
determine a linear model representing a correlation between the integrated current values and the SOC included in the set of state information; and
determine the capacity of the battery based on a slope of the linear model.

13. The apparatus of claim 10, wherein the processor is further configured to:
newly determine capacity of the battery each time the memory stores new battery state information; and
update the capacity of the battery based on a weighted combination of a previously determined capacity and a newly determined capacity.

14. The apparatus of claim 13, wherein the processor is configured to determine a larger weight for the previously determined capacity as a number of excluded pieces of state information among the state information included in the set of state information increases.

15. The apparatus of claim 13, wherein the processor is configured to determine a weight for the previously determined capacity based on consecutiveness of excluded pieces of state information among the state information included in the set of state information.

16. A method of managing a battery in an electrified vehicle, the method comprising:
storing battery state information i including State Of Charge (SOC) and integrated current values collected in a plurality of ignition-on intervals of the electrified vehicle;
determining a set of state information based on a plurality of pieces of the battery state information collected in the plurality of ignition-on intervals of the electrified vehicle;
determining a battery capacity degradation value based on a relationship between the integrated current values and the SOC included in the set of state information; and
providing the battery capacity degradation value to one or more external devices.

17. The method of claim 16, wherein determining the set of state information includes excluding, from the set of state information, battery state information not corresponding to a target operating SOC of the electrified vehicle.

18. The method of claim 16, wherein determining the set of state information further includes excluding, from the set of state information, battery state information including SOC determined at a battery temperature lower than a reference temperature.

19. The method of claim 16, further comprising:
determining the SOC for an ignition-on interval, among the plurality of ignition-on intervals, based on an open circuit voltage of the battery obtained at a beginning of the ignition-on interval; and
determining an integrated current value for the ignition-on interval based on a current supplied by the battery during the ignition-on interval.

20. The method of claim 16, wherein determining the battery capacity degradation value includes:
determining a capacity of the battery based on a slope of a linear model obtained by performing linear regression analysis on a relationship between the integrated current values included and the SOC in the set of state information; and
determining the battery capacity degradation value based on the capacity of the battery.
